(19) United States
(12) Patent Application Publication
(10) Pub. No.: US 2025/0355198 A1
(43) Pub. Date: Nov. 20, 2025

(54) OPTICAL ELEMENTS ON PHOTONIC INTEGRATED CIRCUITS

(71) Applicant: Applied Materials, Inc., Santa Clara, CA (US)

(72) Inventors: Zijiao Yang, Fremont, CA (US); Sihui He, Sunnyvale, CA (US); Guannan Chen, Belmont, CA (US); Kenichi Ohno, Santa Clara, CA (US)

(21) Appl. No.: 19/199,788

(22) Filed: May 6, 2025

Related U.S. Application Data
(60) Provisional application No. 63/647,101, filed on May 14, 2024.

(51) Int. Cl. G02B 6/42; H01L 25/00; H01L 25/16

(52) U.S. Cl. CPC G02B 6/4214; G02B 6/4215; G02B 6/4278; H01L 25/167; H01L 25/50

(57) ABSTRACT

A device includes a photonic integrated circuit (PIC) of a PIC structure. The PIC includes a substrate and a waveguide structure disposed on a first side of the substrate. The waveguide structure includes an optical reflector disposed on a waveguide. The device further includes a set of optical elements of the PIC structure. The set of optical elements is formed on a second side of the substrate opposite the first side of the substrate. The optical reflector is configured reflect an optical signal received from the waveguide toward the set of optical elements.

### CROSS-REFERENCE TO RELATED APPLICATION(S)

The present application claims priority to U.S. Provisional Patent Application No. 63/647,101, filed on May 14, 2024, the entire contents of which are hereby incorporated by reference herein.

### TECHNICAL FIELD

Embodiments of the present disclosure relate to optical systems, and more particularly to implementing optical elements on photonic integrated circuits (PICs).

### BACKGROUND

In an optical system, an optical signal can travel through a waveguide (e.g., optical fiber) that is formed from an inner core made of a first material having a first index of refraction and an outer cladding made of a second material having a second index of refraction less than the first index of refraction. For example, the first material and the second material can each be formed from a different type of glass. Thus, when an optical signal traveling in a waveguide is incident on the boundary between the inner core and the outer cladding at an angle exceeding the critical angle, the optical signal can exhibit total internal reflection. At the boundary, an evanescent wave can be generated from the optical signal. Generally, an evanescent wave is an oscillating wave (e.g., electromagnetic wave or acoustic wave) generated at a boundary between two media and exists only within a very short distance from the boundary. Evanescent waves can exit the waveguide, and their amplitude can decay exponentially as a function of distance from the boundary. Thus, evanescent waves are generally observable in the near field of the optical signal in close proximity to the boundary.

### SUMMARY

In some embodiments, a device is provided. The device includes a photonic integrated circuit (PIC) of a PIC structure. The PIC includes a substrate and a waveguide structure disposed on a first side of the substrate. The waveguide structure includes an optical reflector disposed on a waveguide. The device further includes a set of optical elements of the PIC structure. The set of optical elements is formed on a second side of the substrate opposite the first side of the substrate. The optical reflector is configured reflect an optical signal received from the waveguide toward the set of optical elements.

In some embodiments, a system is provided. The system includes a printed circuit board, an interposer disposed on the printed circuit board, an electronic integrated circuit (EIC) disposed on the interposer, and a photonic integrated circuit (PIC) structure. The PIC structure includes a PIC including a substrate, and a waveguide structure disposed on a first side of the substrate and the EIC. The waveguide structure includes an optical reflector disposed on a waveguide. The PIC structure further includes a set of optical elements formed on a second side of the substrate opposite the first side of the substrate. The optical reflector is configured reflect an optical signal received from the waveguide toward the set of optical elements.

In some embodiments, a method is provided. The method includes obtaining a substrate, forming, on a first side of the substrate, a waveguide structure of a photonic integrated circuit (PIC) of a PIC structure, and forming, on a second side of the substrate opposite the first side of the substrate, a set of optical elements of the PIC structure. The waveguide structure includes an optical reflector disposed on a waveguide, and the optical reflector is configured reflect an optical signal received from the waveguide toward the set of optical elements.

### BRIEF DESCRIPTION OF THE DRAWINGS

The present disclosure is illustrated by way of example, and not by way of limitation, in the figures of the accompanying drawings in which like references indicate similar elements. It should be noted that different references to “an” or “one” embodiment in this disclosure are not necessarily to the same embodiment, and such references mean at least one.

FIG. 1 is a diagram of a perspective view of at least a portion of a co-packaged substrate having one or more electrical and photonic devices formed thereon, in accordance some embodiments.

FIGS. 2A-2B are diagrams of top views of photonic integrated interconnect units, according to some embodiments.

FIGS. 3A-3C are diagrams of example systems implementing optical elements on photonic integrated circuits (PICs), according to some embodiments.

FIGS. 4A-4B are diagrams of example photonic integrated circuit (PIC) structures implementing optical elements on PICs, according to some embodiments.

FIG. 5 is a flow diagram of an example method of implementing a photonic integrated circuit (PIC) structure having optical elements on PICs, according to some embodiments.

FIGS. 6-7B are flow diagrams of example methods of fabricating photonic integrated circuit (PICs) structures implementing optical elements on PICs, according to some embodiments.

### DETAILED DESCRIPTION

Embodiments of the present disclosure relate to implementing optical elements on photonic integrated circuits (PICs). A co-packaged device (e.g., multi-chip module) can include a package substrate having multiple PICs assembled closely together. More specifically, optical components can be integrated on substrates (e.g., silicon (Si) substrate) for fabricating large-scale PICs that co-exist with micro-electronic chips. With the use of an optical transceiver, received optical signal can be converted to an electrical signal capable of being processed by an integrated circuit, or the processed electrical signal can be converted to an optical signal to be transmitted via an optical fiber.

Instead of ICs (e.g., microchips) that utilize electrons to process information, a PIC utilizes photons (light particles) to process information. A PIC can include multiple photonic components connected on a single chip. Examples of components of a PIC include optical signal generators (e.g., lasers) to generate optical signals (e.g., light), waveguides to direct optical signals within the PIC (e.g., similar to wires used to direct electrons), modulators to modulate optical signals to encode information, and detectors to detect and decode the information from the optical signals. PICs can have various advantages over typical ICs. For example, since photons travel at the speed of light, PICs can offer high-speed data transmission. As another example, photons within PICs can experience less signal loss as compared to electrons within typical ICs, which enables more energy-efficient operation.

A co-packaged device can include an interconnect device (“interconnect”) disposed between a first component and a second component. For example, an interconnect can be a placed between a package substrate and a ball grid array. In some embodiments, an interconnect includes an interposer. An interposer is an electrical interface that routes connections between sockets or connections between the first component and the second component. An interposer can be used to connect components that may not naturally connect to one another. Some interconnects (e.g., interposers) can include multiple conductive layers (e.g., metal layers), where pairs of conductive layers are connected by at least one conductive via (“via”). For example, a first conductive layer of a first metallization level and a second conductive layer of a second metallization level can be connected by at least one via. Some interconnects (e.g., interposers) can further include multiple waveguides integrated near the conductive layers. The waveguides of an interconnect can use evanescent wave coupling to transmit an optical signal received from an initial waveguide of the interconnect to a final waveguide of the interconnect. For example, the initial waveguide can be integrated near a bottom conductive layer of the interconnect, and the final waveguide can be integrated near a top conductive layer of the interconnect.

Optical fiber connectors, or attachments, can be used to connect PICs of a co-packaged device to external devices via optical fibers. No single optical fiber connector solution exists that meets scalability, manufacturability, suitable alignment tolerance and pluggability. Accordingly, optical fiber connectors are one of the biggest challenges to the mass production of photonic devices (e.g., photonic ICs).

Aspects and implementations described herein can address these and other drawbacks by implementing optical elements on PICs. A PIC can be formed on a substrate. The substrate can include any suitable material. Examples of suitable materials that can be included in the substrate include silicon (Si), silicon-on-insulator (SOI), glass, lithium niobate (LiNbO₃), sapphire, magnesium oxide (MgO), silicon carbide (SiC), carbon (C) (e.g., diamond), and/or any optically transparent substrate material.

A PIC can further include a waveguide formed on a first side of the substrate. The waveguide can include an inner core formed within a cladding structure, and an optical reflector (e.g., mirror) for light coming from the inner core. In some embodiments, the optical reflector is an angled mirror disposed on a trench formed within the cladding structure. In some embodiments, the optical reflector is a mirror located above a grating coupler formed within the waveguide. The inner core can be formed from any suitable material. Examples of materials that can be used to form inner cores include a silicon nitride (SiₓN_{y}), a silicon oxide (SiOₓ) LiNbO₃, glass, Si, etc.

A set of optical elements (e.g., an array of optical elements) can be formed on a second side of the substrate opposite the first side. More specifically, the set of optical elements can be formed within one or more layers (e.g., films), which is formed on the second side of the substrate. The set of optical elements arranged on the backside of the PIC can be arranged to receive light reflected off the optical reflector. For example, the arrangement of the set of optical elements can have different refractive index from their matrix. The positions of the optical reflector and/or the optical elements can be optimized to enable the array of optical elements to maximally couple the light reflected off the optical reflector. The backside can increase the path length of light expansion.

In some embodiments, the first side of the substrate is a frontside of the substrate corresponding to a frontside of the PIC, and the second side of the substrate is a backside of the substrate corresponding to a backside of the PIC. In these embodiments, the waveguide structure can be arranged on the frontside of the PIC and the set of optical elements can be arranged on the backside of the PIC.

In some embodiments, the second side of the substrate is the backside of the substrate corresponding to the backside of PIC, and the second side of the substrate is the frontside of the substrate corresponding to the frontside of the PIC. In these embodiments, the waveguide structure can be arranged on the backside of the PIC and the set of optical elements can be arranged on the frontside of the PIC.

The array of optical elements can function as optical input/output (I/O) to optical fibers of an optical fiber connector, or attachment, to be coupled to the PIC. For example, the array of optical elements can collimate light to increase alignment tolerance between the waveguide and optical fibers of the optical fiber connector to be coupled to the PIC. The array of optical elements arranged on the backside of the PIC can include any suitable optical elements and/or combinations of optical elements in accordance with embodiments described herein.

In some embodiments, the set of optical elements includes one or more metalenses. A metalens is an ultra-thin, flat optical element that can focus or manipulate light. For example, a metalens can interact with light, altering its phase, amplitude, and/or polarization. By precisely controlling the shape, size, and/or arrangement of a metalens, the metalens can be designed to achieve various optical functions, such as focusing, beam shaping, creating holographic images, etc. Multiple metalenses can form a metalens array on the backside of the PIC. A metalens can have sub-wavelength dimensions. In some embodiments, a metalens has a dimension that ranges from about 0.5 micrometer (μm) to about 2 μm. A metalens can be formed from any suitable material. The type of material can depend on a variety factors, such as target wavelength (visible light, infrared, etc.), efficiency, ease of fabrication, cost, etc. Examples of materials that can be used to form a metalens include Si, dielectric materials (e.g., titanium dioxide (TiO₂) and gallium nitride (GaN)), semiconductor materials (e.g., silicon nitride (SiN) and zinc selenide (ZnSe)), phase-change materials (e.g., germanium-antimony-tellurium (GST) or vanadium dioxide (VO₂)), transition metal dichalcogenides (e.g., molybdenum disulfide (MoS₂), tungsten disulfide (WS₂), tungsten diselenide (WSe₂), molybdenum ditelluride (MoTe₂), or rhenium disulfide (ReS₂)), ferroelectric materials (e.g., barium titanate (BaTiO₃ or BTO) or strontium titanate (SrTiO₃ or STO)), carbon (C) (e.g., graphene), metals (e.g., gold (Au) or silver (Ag)), etc.

In some embodiments, the set of optical elements includes one or more microlenses. A microlens can have a sphere or hemisphere shape that can function based on similar principles as traditional curved lens. A microlens can have a diameter typically less than 1 millimeter (mm). In some embodiments, a microlens has a diameter that ranges from about 100 μm to about 200 μm. The small size of microlenses can enable microlenses to focus light onto specific points. Microlenses can be formed from polymers, glass or other suitable optical materials. The type of material can depend on a variety factors, such as target wavelength (visible light, infrared, etc.), application (imaging, sensing, light coupling, etc.) efficiency, ease of fabrication, cost, etc. Examples of polymers that can be used to form a microlens include polymethyl methacrylate (PMMA), polycarbonate (PC), epoxy, etc. Examples of glasses that can be used to form a microlens include fused silica (SiO₂), chalcogenide glass, others optical glasses, etc.

Embodiments described herein can provide for numerous other technical advantages. For example, embodiments described herein can be used to form an optical I/O for optical fibers of optical fiber connectors to PICS with increased scalability, manufacturability, alignment tolerance, pluggability, etc.

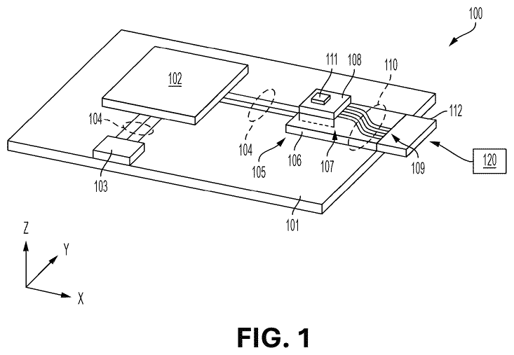

FIG. 1 is a diagram of a perspective view of a system including a co-packaged device 100, in accordance some embodiments. The co-packaged device 100 can include an electrical or opto-electrical chip (“chip”) 102 connected by a waveguides or electrical trace interconnect 104 to a photonic integrated interconnect unit 103 where all are formed on or disposed on a package substrate 101. In some embodiments, the chip 102 includes any high-density chip having a high input/output (I/O) pin count. In one example, the high-density chip has between 100 and 2000 I/O pins or up to and greater than 2000 I/O pin counts. For example, the chip 102 can be a data center SWITCH chips, an artificial intelligence (AI) chip, etc.

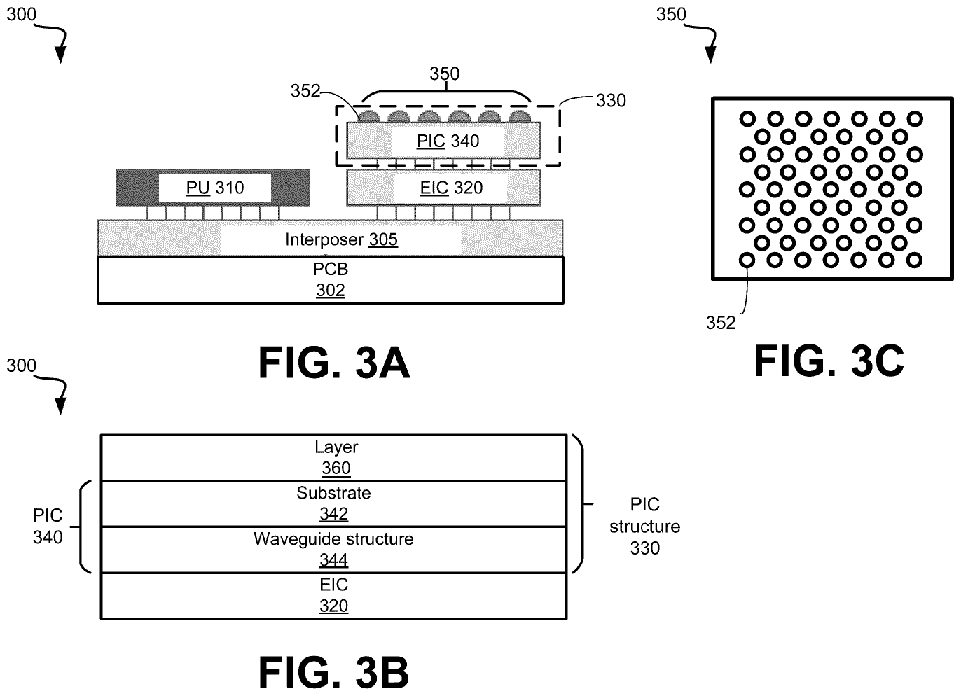

The photonic integrated interconnect unit 103 includes a fiber connector region configured to be coupled to a fiber connector 112 for removably connecting a fiber cables 120 to the photonic integrated interconnect unit 103. In some embodiments, the fiber cables 120 is plugged into the fiber connector 112 to operably connect the fiber cables 120 to the co-packaged device 100. In an embodiment, the photonic integrated interconnect unit 103 is configured for connecting fiber cables 120 including, but not limited to, single-mode fiber optic cables having 9 μm fiber core diameters. The fiber connector 112 may further include optical fibers 112A (FIG. 4) to operably connect fiber cables 120 having between 1 to 74 fiber cores, 74 to 148 fiber cores, and up to and greater than 148 fiber cores to the photonic integrated interconnect unit 103.

In some embodiments, the photonic integrated interconnect unit 103 is configured to transmit signals between the chip 102 and the fiber cables 120 connected to the photonic integrated interconnect unit 103. The photonic integrated interconnect unit 103 includes a photonic glass layer (PGL) substrate 106, optical structures 110₁-110_{N} formed integral with or on the PGL substrate 106, an optical transceiver integrated circuit (chip) 108 mounted on the PGL substrate 106 and coupled to the optical structures 110₁-110_{N} at a first interface 107, and the fiber connector 112 connected to both the PGL substrate 106 and the optical structures 110₁-110_{N} at a second interface 109.

The chip 108 operates to convert electrical signals to optical signals, and vice versa. In some embodiments, the chip 108 is a silicon photonic (SiPho) chip. The optical structures 110₁-110_{N} operate to transmit optical signals between the chip 108 and the fiber connector 112, and the photonic waveguide or electrical trace interconnect 104 operate to transmit electrical or optical signals between the photonic integrated interconnect unit 103 (e.g., the chip 108) and the chip 102. The photonic waveguide or electrical trace interconnect 104 can include metal traces that are formed within the package substrate 101, which in some embodiments can include metal traces formed in a printed circuit board (PCB) substrate or metal traces formed within multiple redistribution layers (e.g., dielectric containing layers) formed over a solid core substrate (e.g., silicon or glass core substrate).

A photonic engine 105 may optionally further include one or more electronic phy chips 111 that are coupled to the chip 108. The electronic phy chip 111 is generally used to assist with operations performed by an optical chip. In some embodiments, the electronic phy chip 111 is operably connected to the chip 108 to assist the chip 108 with various electrical functions. As shown, the electronic phy chips 111 may be mounted on top of the chip 108 and thereby directly connected to the chip 108. Alternatively, the electronic phy chip 111 may be embedded in the PGL substrate 106 and connected to the chip 108 through the PGL substrate 106. Further, the electronic phy chip 111 can be mounted on or embedded in the package substrate 101 and connected to the chip 108 through electrical trace interconnect 104.

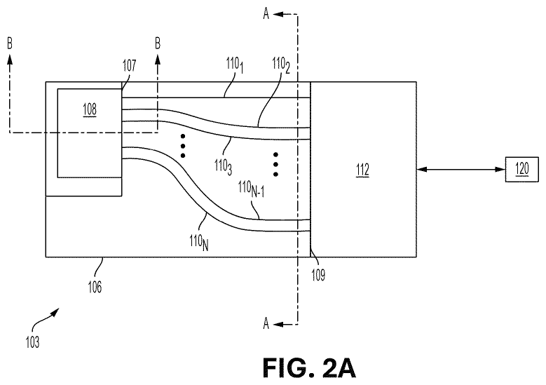

FIGS. 2A-2B are diagrams of top views of the photonic engine 105, according to some embodiments. As shown in FIG. 2A, the photonic engine 105 includes the chip 108 mounted near one end of the PGL substrate 106, the fiber connector 112 connected at an opposite end of the PGL substrate 106 from the chip 108, and the optical structures 110₁-110_{N} extending between the chip 108 and the fiber connector 112. In some embodiments, each of the optical structures 110₁-110_{N} include a light transmitting region for transmitting light in either direction between the first interface 107 and the second interface 109. The light being transmitted through the optical structures can be either received from one or more waveguides 108A (FIG. 2B) of the chip 108 or received from one or more optical fibers within the fiber connector 112 that a light signal source is in communication with during use. The chip 108 is typically configured to receive light (e.g., detect) transmitted through the optical structures 110₁-110_{N} and also emit light (e.g., transmit) into the optical structures 110₁-110_{N} in an effort to communicate with external devices connected through the fiber connector 112. The chip 108 can be configured to transmit light into the optical structures 110₁-110_{N} by at least the use of light emitters integrated into chip 108, or by use of light emitters that are external to PGL substrate 106. In the case where the light emitters are external to PGL substrate 106 the light is delivered to chip 108 via the optical structures 110₁-110_{N} and then modulated by the chip 108 to create a transmit signal that is provided to the optical structures 110₁-110_{N}. In some embodiments, which can be combined with other embodiments described herein, the optical structures 110₁-110_{N} are formed on (e.g. directly or indirectly) or are integral with the PGL substrate 106.

In some embodiments, which can be combined with other embodiments described herein, the light transmitting region within each of the optical structures 110₁-110_{N} may have the same cross-sectional dimensions, such as height and width. In another embodiment, which can be combined with other embodiments described herein, the light transmitting region within at least one of the optical structures 110₁-110_{N} may have at least one different cross-sectional dimensions, such as one of height and width, from the dimensions of the other optical structures 110 within the PGL substrate 106. In one embodiment, which can be combined with other embodiments described herein, the light transmitting region within each of the optical structures 110₁-110_{N} may have the same refractive index. In another embodiment, which can be combined with other embodiments described herein, the light transmitting region within at least one of the optical structures 110₁-110_{N} may have a different refractive index or multiple different refractive indexes or a gradual gradation of refractive indexes or other index varying structures when compared with the rest of the optical structures 110₁-110_{N} within the PGL substrate 106.

In some embodiments, the number of optical structures 110₁-110_{N} formed in the PGL substrate 106 is dependent on the number of waveguides 108A in the chip 108 needing to be connected, which may also correspond with the number of fiber connections to be connected to the chip 102. In some embodiments, the chip 102 may comprise 72 fiber connections such that 72 electrical trace interconnects 104 correspondingly extend from the chip 102 and connect to 72 corresponding fibers and waveguides 108A in the chip 108 of the photonic engine 105. To appropriately connect the chip 108 to the fiber connector 112 via the optical structures 110₁-110_{N} in the PGL substrate 106, seventy-two (72) corresponding optical structures 110₁-110_{N} are formed on or integral with the PGL substrate 106. In this example, as shown in FIGS. 2A-2B, N equals 72, and thus the optical structures 110₁-110_{N} are spaced apart in the X-Y plane from one edge of the PGL substrate 106 to the other edge of the PGL substrate 106. In this example, optical structure 110₁ is positioned near the top-most edge and optical structure 11072 would be positioned closest to the bottom most edge of FIG. 2A. As discussed further below, the optical structures 110₁-110_{N} are spaced apart and separated by a material that has different optical properties, such as index of refraction (n), than the light transmitting portions of the optical structures 110₁-110_{N}.

The optical structures 110₁-110_{N} are generally sized and configured to appropriately connect to the waveguides 108A within the chip 108. In an embodiment, the waveguides 108A (FIG. 2B) at the output of the chip 108, or portion that is to communicate with the optical structures, have a core with a height dimension that is about 1 μm in cross-sectional size. In one configuration, the output of the chip 108 has a square or rectangular shaped cross-section that has at least one dimension that is equal to about 1 μm in length. For example, a square cross-section of a waveguide 108A may have a core that is 1 μm height and width. Light transmitted to and from the chip 108 would thus be transferred through the 1 μm waveguides 108A.

In contrast, light transmitted to and from the fiber cables 120 through the fiber connector 112 can have a different form factor, such as having a core cross sectional dimension of about 9 μm in size. For example, the fiber connector 112 may have a square, rectangular or circular cross-section with a core having a height dimension that is about 9 μm in size. As such, in some embodiments, each of the optical structures 110₁-110_{N} is formed such that light propagating through the optical structures 110₁-110_{N} between the chip 108 and the fiber cables 120 is expanded or compressed accordingly depending on the direction of propagation of the optical signal. In one example, the optical structures 110₁-110_{N} extending from the second interface 109 adjacent to the 9 μm fibers in the fiber connector 112 have transmission regions with cross-sectional areas that vary at different portions of the respective structures to facilitate coupling to the 1 μm waveguides 108A in the chip 108. In one embodiment, the optical structures 110₁-110_{N} are tapered along at least a portion of their length from a 9 μm dimensional core size until they are near 1 μm dimensional core size near the first interface 107, where it is assumed that the varying dimensional core size relates to a dimension of a side of a square or rectangular cross-sectional shaped optical structure. In some embodiments, tapered optical structures 110₁-110_{N} have a cross-sectional area ratio, which if measured at one end versus measured at the opposing end of the optical structure 110 is greater that 1:1 and less than about 1:100, or less than 1:81. In some embodiments, the optical structures 110₁-110_{N} extending from the second interface 109 adjacent to the fiber connector 112 have a varying refractive index along at least a portion of their length from the second interface 109 to the first interface 107 to facilitate coupling between the optical elements within the chip 108 and the fiber connector 112 that have different cross-sectional dimensions.

In another aspect, the photonic engine 105 is configured such that the transmission loss of the optical signal between the first interface 107 and the second interface 109 is approximately or less than 3 dB, inclusive of loss due to the transmission of the optical signal through the optical structures 110₁-110_{N} themselves. In some embodiments, the transmission loss may largely be dependent on the coupling at the first interface 107 between the chip 108 and the optical structures 110₁-110_{N}. As shown in FIG. 2B, in an embodiment, the chip 108 is to be mounted on a coupling surface 208 at a chip mounting region 204 of the PGL substrate 106. When mounted on chip mounting region 204, the waveguides 108A disposed on the side surface 108B of the chip 108 are aligned with the optical structures 110₁-110_{N} found at the first interface 107.

In some embodiments, the PGL substrate 106 further includes one or more fiducial marks 206 to assist in the alignment and mounting of the chip 108 on the chip mounting region 204. The one or more fiducial marks 206 operate to guide and help align the position of the chip 108 along the X-Y plane of the PGL substrate 106 to ensure mounting of the chip 108 occurs with proper alignment to one or more electrical contacts (e.g., vias 1006) and optical structure portions of the PGL substrate 106. As such, in an embodiment, the tolerance for error in the coupling or hybrid bonding the chip 108 and the optical structures 110₁-110_{N} together at the first interface 107, which will be discussed further below, may be in a range from 0.1 to 2 ums to ensure the connections are optimized for the lowest signal loss. In one embodiment, the misalignment of the centers of the waveguides 108A and the optical structures 110₁-110_{N} is maintained such that the lateral misalignment in the Y-direction (i.e., top to bottom direction in FIG. 2B) is less than 1 to 2 ums. In some embodiments, the misalignment of the centers of the waveguides 108A and the optical structures 110₁-110_{N} is also maintained such that the vertical misalignment in the Z-direction is less than 1 to 2 ums. In one embodiment, the variability in the vertical misalignment can be dependent on the variability of the compression of solder balls 1010 or other electrical contact that is used to electrically couple the chip 108 to vias formed in a portion of the PGL substrate 106.

FIGS. 1-2B have described optical photonic devices having multiple optical structures formed on a substrate (e.g., glass substrate). The optical photonic device can include a photonic chip mounted on the photonic substrate and connected to multiple optical structures. The optical structures optically connect the photonic chip to a fiber connector configured to connect with an external fiber and operate to propagate light signals between the fiber connector and the photonic chip.

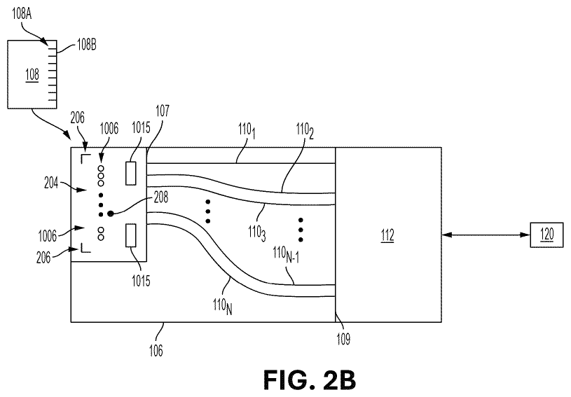

FIGS. 3A-3B are diagrams of an example apparatus or system 300, according to some embodiments. As shown in FIG. 3A, system 300 can include printed circuit board (PCB) 302, interconnect (e.g., interposer) 305, at least one processing unit (PU) 310 disposed on interconnect 305, at least one electronic integrated circuit (EIC) 320 disposed on interconnect 305, and at least one PIC structure 330 disposed on the at least one EIC 320. Other components that can be used to enable system 300, such as network interface cards (NICs), serializer-deserializers (SERDES), etc. have been omitted for simplicity.

PIC structure 330 can include PIC 340 and set of optical elements (“set”) 350 including optical elements 352 formed on a side of PIC 340. In some embodiments, set 350 is formed on a backside of PIC 340. In some embodiments, set 350 is formed on a frontside of PIC 340. Set 350 can function as an optical input/output (I/O) to optical fibers of an optical fiber connector, or attachment, to be coupled to PIC 340.

More specifically, as shown in FIG. 3B, PIC 340 can include substrate 342. Substrate 342 can include any suitable material. Examples of suitable materials that can be included in substrate 342 include Si, SOI, glass, LiNbO₃, sapphire, MgO, SiC, C (e.g., diamond), and/or any optically transparent substrate material.

As further shown in FIG. 3B, PIC 340 can further include waveguide structure 344 formed on a first side of substrate 342 and layer (e.g., film) 360 formed on a second side of substrate 342 opposite the first side. More specifically, and as will be described in further detail below with reference to FIGS. 4A-4B, set 350 can be formed within layer 360. In some embodiments, the first side of substrate 342 is a frontside of substrate 342 corresponding to a frontside of PIC 340, and the second side of substrate 342 is a backside of substrate 342 corresponding to a backside of PIC 340. In some embodiments, the first side of substrate 342 is the backside of substrate 342, and the second side of substrate 342 is the front of substrate 342.

As will be described in further detail below with reference to FIGS. 4A-4B, waveguide structure 344 can include an inner core formed within a cladding structure, and an optical reflector (e.g., mirror) for light coming from the inner core. In some embodiments, and as will be described in further detail below with reference to FIG. 4A, the optical reflector is an angled mirror disposed on a trench formed within the cladding layer. In some embodiments, and as will be described in further detail below with reference to FIG. 4B, the optical reflector is a mirror located above a grating coupler formed within the waveguide. For example, as will be described in further detail below with reference to FIGS. 4A-4B, set 350 can collimate light to increase alignment tolerance between the waveguide and optical fibers of the optical fiber connector to be coupled to PIC 340. The optical elements of set 350 can be arranged to receive light reflected off the optical reflector. The positions of optical reflector and/or the optical elements of set 350 can be optimized to enable set 350 to maximally couple the light reflected off the optical reflector. The backside can increase the path length of light expansion. An example top-down view of a set 350 including optical element 352 is shown in FIG. 3C.

Set 350 can include any suitable optical elements and/or combinations of optical elements in accordance with embodiments described herein. In some embodiments, set 350 includes one or more metalenses (e.g., optical element 352 is a metalens). A metalens is an ultra-thin, flat optical element that can focus or manipulate light. For example, a metalens can interact with light, altering its phase, amplitude, or polarization. By precisely controlling the shape, size, and arrangement of a metalens, the metalens can be designed to achieve various optical functions, such as focusing, beam shaping, creating holographic images, etc. Multiple metalenses can form a metalens array on the backside of the PIC. A metalens can have sub-wavelength dimensions. In some embodiments, a metalens has a dimension that ranges from about 0.5 μm to about 2 μm. A metalens can be formed from any suitable material. The type of material can depend on a variety factors, such as target wavelength (visible light, infrared, etc.), efficiency, ease of fabrication, cost, etc. Examples of materials that can be used to form a metalens include Si, dielectric materials (e.g., TiO₂ and GaN), semiconductor materials (e.g., SiN and ZnSe), phase-change materials (e.g., GST) or VO₂), transition metal dichalcogenides (e.g., MoS₂, WS₂, WSe₂, MoTe₂ or ReS₂), ferroelectric materials (e.g., BTO or STO), C (e.g., graphene), metals (e.g., Au or Ag), etc.

In some embodiments, set 350 includes one or more microlenses (e.g., optical element 352 is a microlens). A microlens can have a sphere or hemisphere shape that can function based on similar principles as traditional curved lens. A microlens can have a diameter typically less than 1 mm. In some embodiments, a microlens has a diameter that ranges from about 100 μm to about 200 μm. The small size of microlenses can enable microlenses to focus light onto specific points. Microlenses can be formed from polymers, glass or other suitable optical materials. The type of material can depend on a variety factors, such as target wavelength (visible light, infrared, etc.), application (imaging, sensing, light coupling, etc.) efficiency, ease of fabrication, cost, etc. Examples of polymers that can be used to form a microlens include PMMA, PC, epoxy, etc. Examples of glasses that can be used to form a microlens include fused SiO₂, chalcogenide glass, others optical glasses, etc. Further details regarding PIC structure 330, including PIC 340 and the set 350 will now be described below with reference to FIGS. 4A-4B.

FIG. 4A is diagram of a PIC structure 400A, according to some embodiments. PIC structure 400A can correspond to PIC structure 330 of FIGS. 3A-3C. For example, as shown in FIG. 4A, PIC structure 400A can include PIC 340 including substrate 342, waveguide structure 344 formed on the first side of substrate 342 (e.g., frontside or backside), and set 350 within layer 360 formed on a second side of substrate 342 (e.g., backside or frontside).

As further shown in FIG. 4A, waveguide structure 344 can include a cladding structure including cladding material 410A-1 and cladding material 410A-2, and inner core 420 formed within the cladding structure between cladding materials 410A-1 and 410A-2. In some embodiments, cladding materials 410A-1 and 410A-2 are dielectric materials. For example, at least one of cladding material 410A-1 or cladding material 410A-2 can include silicon dioxide. Inner core 420A can include any suitable material. Examples of materials that can be used to form inner core 420A include SiₓN_{y}, SiOₓ, LiNbO₃, glass, Si, etc. Optical reflector 430A is formed within trench 435 of waveguide structure 344. More specifically, optical reflector 430A is an angled optical reflector (e.g., angled mirror). Optical reflector 430A is designed to reflect light from inner core 420A and direct the light toward set 350. As shown in FIG. 4A, set 350 can collimate the light to generate collimated light 440A, which can be received by optical fibers of an optical fiber connector.

FIG. 4B is diagram of a PIC structure 400B, according to some embodiments. PIC structure 400B can correspond to PIC structure 330 of FIGS. 3A-3C. For example, as shown in FIG. 4B, PIC structure 400B can include PIC 340 including substrate 342, waveguide structure 344 formed on the first side of substrate 342 (e.g., frontside or backside), and set 350 within layer 360 formed on a second side of substrate 342 (e.g., backside or frontside).

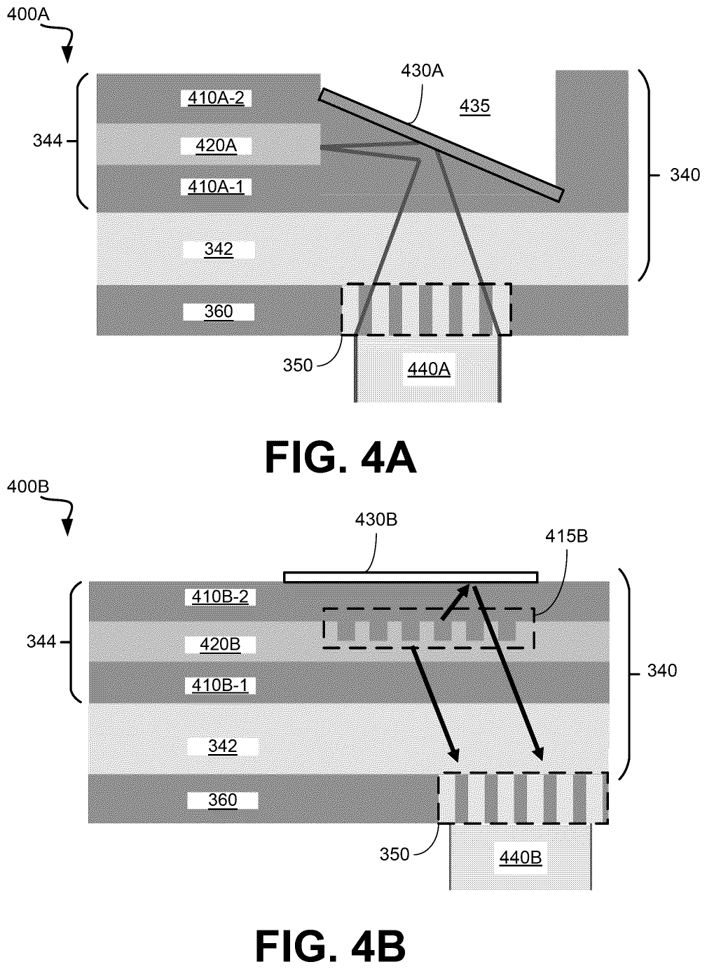

As further shown in FIG. 4A, waveguide structure 344 can include a cladding structure including cladding material 410B-1 and cladding material 410B-2, and inner core 420B formed within the cladding structure between cladding materials 410B-1 and 410B-2. In some embodiments, cladding materials 410-1 and 410-2 are dielectric materials. For example, at least one of cladding material 410B-1 or cladding material 410B-2 can include silicon dioxide. Inner core 420B can include any suitable material. Examples of materials that can be used to form inner core 420B include SiN, LiNbO₃, glass, Si, etc. In this example, grating coupler 415B is formed within waveguide structure 344, and an optical reflector 430B is formed on cladding material 410B-2 above grating coupler 415B. More specifically, optical reflector 430B is a flat optical reflector (e.g., flat mirror). Optical reflector 430B is designed to reflect light from grating coupler 415B to set 350. As shown in FIG. 4B, set 350 can collimate the light to generate collimated light 440B, which can be received by optical fibers of an optical fiber connector. Further details regarding fabricating PIC structures implementing optical elements on PICs (e.g., PIC structure 400B and/or PIC structure 400B) will now be described below with reference to FIGS. 5-7B.

FIG. 5 is a flow diagram of an example method 500 of forming a system including a PIC structure, according to some embodiments. For example, the system can be similar to the system 300 of FIGS. 3A-3C, and the PIC structure can be similar to the PIC structure 330 of FIGS. 3A-3C, the PIC structure 400B of FIG. 4A and/or the PIC structure 400B of FIG. 4B.

At block 510, a PIC structure is obtained. For example, the PIC structure can include a substrate, a PIC disposed on a first side of the substrate, and a set of optical elements disposed on a second side of the substrate opposite the first side of the substrate. More specifically, the set of optical elements can be formed within a layer disposed on the second side of the substrate. In some embodiments, the first side of the substrate is a frontside of the substrate corresponding to a frontside of the PIC and the second side of the substrate is backside of the substrate corresponding to a backside of the PIC. In some embodiments, the first side of the substrate is the backside, and the second side of the substrate is the frontside.

The PIC can include a waveguide structure including a waveguide. The waveguide can include an inner core disposed within cladding material. The PIC can further include an optical reflector. In some embodiments, the optical reflector is an angled optical reflector (e.g., angled mirror) formed on an angled surface of a trench within the waveguide (e.g., within the cladding material). For example, the PIC structure can be similar to the PIC structure 400B of FIG. 4A. In some embodiments, a grating coupler is formed within the waveguide, and the optical reflector is a flat optical reflector (e.g., flat mirror) formed above the grating coupler. For example, the PIC structure can be similar to the PIC structure 400B of FIG. 4B.

In some embodiments, the set of optical elements is an array of optical elements. The set of optical elements can include any suitable optical element and/or combination of optical elements in accordance with embodiments described herein. In some embodiments, the set of optical elements includes one or more metalenses. In some embodiments, the set of optical elements include one or more microlenses.

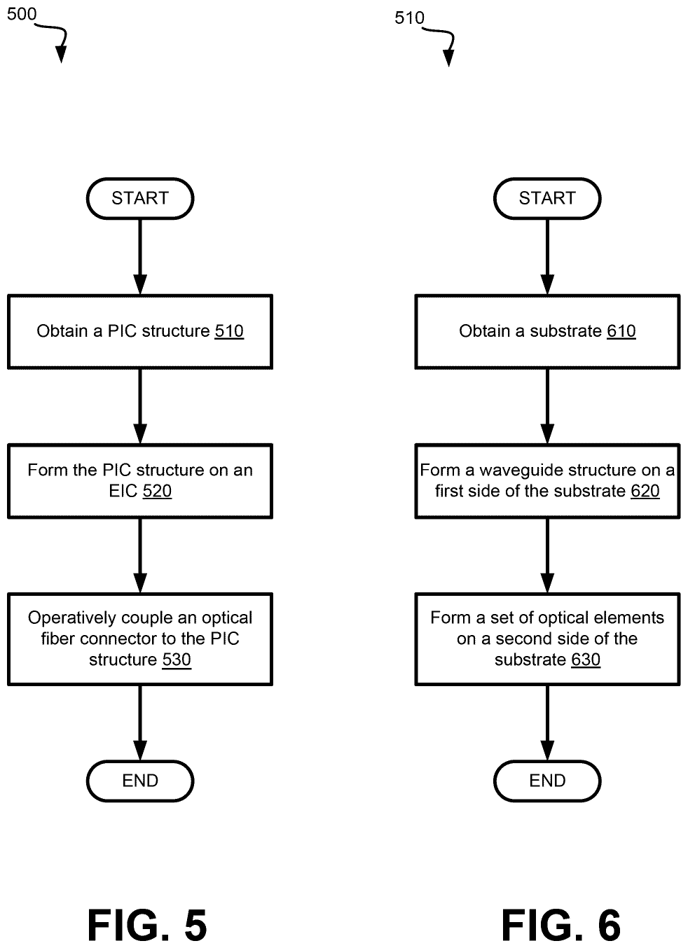

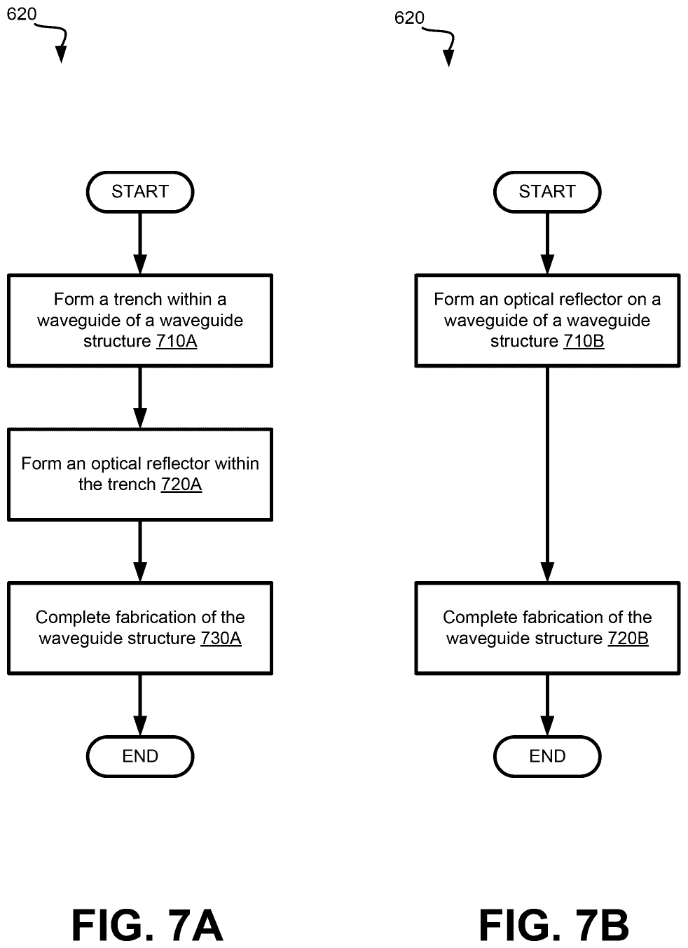

In some implementations, obtaining the PIC structure includes forming the PIC structure. Further details regarding forming the PIC structure will be described below with reference to FIGS. 6-7B.

At block 520, the PIC structure is formed on an EIC. For example, the EIC can be formed on an interposer disposed on a PCB. At least one processing unit can be disposed on the interposer adjacent to the EIC.

At block 530, an optical fiber connector is operatively coupled to the PIC structure. More specifically, the optical fiber connector can be configured to receive optical signals from the set of optical elements. Further details regarding blocks 510-530 are described above with reference to FIGS. 3A-4B and will now be described below with reference to FIGS. 6-7B.

FIG. 6 is a flow diagram of an example method of forming a PIC structure at block 510, according to some embodiments. For example, the PIC structure can be PIC structure 330 of FIGS. 3A-3C, PIC structure 400A of FIG. 4A and/or PIC structure 400B of FIG. 4B.

At block 610, a substrate is obtained. The substrate can include any suitable material. Examples of suitable materials that can be included in the substrate include Si, SOI, glass, LiNbO₃, sapphire, MgO, SiC, C (e.g., diamond), and/or any optically transparent substrate material.

At block 620, a waveguide structure is formed on a first side of the substrate. The waveguide structure can include a waveguide and an optical reflector disposed on the waveguide. The waveguide can include an inner core disposed within cladding material. The cladding material can include any suitable dielectric material (e.g., SiOₓ). Examples of materials that can be used to form the inner core include a silicon SiₓN_{y}, SiOₓ, LiNbO₃, glass, Si, etc. In some embodiments, forming the waveguide structure includes forming at least one of the waveguide or the optical reflector.

In some embodiments, the optical reflector is an angled optical reflector (e.g., angled mirror) formed on an angled surface of a trench within the waveguide (e.g., within the cladding material). For example, the PIC structure can be similar to the PIC structure 400A of FIG. 4A. An example method of forming an angled optical reflector on an angled surface of a trench within the waveguide will be described below with reference to FIG. 7A.

In some embodiments, a grating coupler is formed within the waveguide, and the optical reflector is a flat optical reflector (e.g., flat mirror) formed above the grating coupler. For example, the PIC structure can be similar to the PIC structure 400B of FIG. 4B. An example method of forming a flat optical reflector above a grating coupler formed within the waveguide will be described below with reference to FIG. 7B.

At block 630, a set of optical elements is formed on a second side of the substrate. More specifically, the second side of the substrate is opposite the first side of the substrate. In some embodiments, the first side of the substrate is a frontside of the substrate corresponding to a frontside of a PIC and the second side of the substrate is backside of the substrate corresponding to a backside of the PIC. In some embodiments, the first side of the substrate is the backside, and the second side of the substrate is the frontside.

For example, forming the set of optical elements can include forming a layer on the second side of the substrate, and forming the set of optical elements within the layer formed on the second side of the substrate. In some embodiments, the second side of the substrate is a backside of the substrate. In some embodiments, the set of optical elements is an array of optical elements. The set of optical elements can include any suitable optical element and/or combination of optical elements in accordance with embodiments described herein. In some embodiments, the set of optical elements includes one or more metalenses. In some embodiments, the set of optical elements include one or more microlenses. Further details regarding blocks 610-630 are described above with reference to FIGS. 3A-5 and will now be described below with reference to FIGS. 7A-7B.

FIG. 7A is a flow diagram of an example method of forming a waveguide structure of a PIC at block 620, according to some embodiments. For example, the waveguide structure can be similar to the waveguide structure 344 of FIGS. 7A-7B and FIG. 4A.

At block 710A, a trench is formed within a waveguide of a waveguide structure. The trench can have an exposed surface. In some embodiments, the exposed surface is an angled surface. The trench can be formed using any suitable etch process. In some embodiments, the trench is formed using gray-tone lithography. Gray-tone lithography is a photolithography technique that utilizes a mask with varying opacity levels. That is, the mask is a specially designed photoresist that does not have a simple binary response to light (neither completely exposed nor completely unexposed). More opaque areas can block the light used to expose a light-sensitive resist, resulting in varying depths of etching, and thus different grey tones. Instead, the solubility of the photoresist can vary depending on the intensity of light that the photoresist is exposed to. This can create a resist profile with varying thicknesses across the pattern. In some embodiments, an anti-reflective coating (ARC) is formed at an edge of the waveguide.

At block 720A, an optical reflector is formed within the trench. In some embodiments, the optical reflector is a mirror. More specifically, the optical reflector can be formed on the exposed surface of the trench. In some embodiments, the optical reflector is an angled optical reflector (e.g., angled mirror) formed on an angled surface of the trench. The waveguide structure can be formed on a first side of a substrate of a PIC structure. The optical reflector is designed to reflect an optical signal (e.g., light) received from waveguide (e.g., the inner core) toward a set of optical elements formed on a second side of the substrate opposite the first side. For example, the first side of the substrate can correspond to a frontside of the PIC structure and the second side of the substrate can correspond to a backside of the PIC structure.

At block 730A, fabrication of the waveguide structure is completed. In some embodiments, completing fabrication of the waveguide structure comprises filling a gap existing between an exposed surface of the optical reflector and an exposed surface of the cladding material. Filling the gap can include depositing a gap fill material (e.g., dielectric material) on the optical reflector, and planarizing the gap fill material. Further details regarding blocks 710A-730A are described above with reference to FIGS. 3A-6.

FIG. 7B is a flow diagram of an example method of forming a waveguide structure of a PIC at block 620, according to some embodiments. For example, the waveguide structure can be similar to the waveguide structure 344 of FIGS. 3A-3B and FIG. 4B.

At block 710B, an optical reflector is formed on a waveguide of a waveguide structure. In some embodiments, the optical reflector is a mirror. In some embodiments, forming the optical reflector includes aligning and patterning the optical reflector prior to depositing the optical reflector. More specifically, a grating coupler can be formed within the waveguide, and the optical reflector can be a flat optical reflector formed above the grating coupler. The waveguide structure can be formed on a first side of a substrate of a PIC structure. The optical reflector is designed to reflect an optical signal (e.g., light) received from the grating coupler toward a set of optical elements formed on a second side of the substrate opposite the first side. For example, the first side of the substrate can correspond to a frontside of the PIC structure and the second side of the substrate can correspond to a backside of the PIC structure.

At block 720B, fabrication of the waveguide structure is completed. In some embodiments, completing fabrication of the waveguide structure comprises applying a protective coating to the optical reflector. Further details regarding blocks 710B-720B are described above with reference to FIGS. 3A-6.

The preceding description sets forth numerous specific details such as examples of specific systems, components, methods, and so forth, in order to provide a good understanding of several embodiments of the present disclosure. It will be apparent to one skilled in the art, however, that at least some embodiments of the present disclosure may be practiced without these specific details. In other instances, well-known components or methods are not described in detail or are presented in simple block diagram format in order to avoid unnecessarily obscuring the present disclosure. Thus, the specific details set forth are merely exemplary. Particular implementations may vary from these exemplary details and still be contemplated to be within the scope of the present disclosure.

As used herein, the singular forms “a,” “an,” and “the” include plural references unless the context clearly indicates otherwise. Thus, for example, reference to “a precursor” includes a single precursor as well as a mixture of two or more precursors; and reference to a “reactant” includes a single reactant as well as a mixture of two or more reactants, and the like.

Reference throughout this specification to “one embodiment” or “an embodiment” means that a particular feature, structure, or characteristic described in connection with the embodiment is included in at least one embodiment. Thus, the appearances of the phrase “in one embodiment” or “in an embodiment” in various places throughout this specification are not necessarily all referring to the same embodiment. In addition, the term “or” is intended to mean an inclusive “or” rather than an exclusive “or.” When the term “about” or “approximately” is used herein, this is intended to mean that the nominal value presented is precise within +10%, such that “about 10” would include from 9 to 11.

The term “at least about” in connection with a measured quantity refers to the normal variations in the measured quantity, as expected by one of ordinary skill in the art in making the measurement and exercising a level of care commensurate with the objective of measurement and precisions of the measuring equipment and any quantities higher than that. In certain embodiments, the term “at least about” includes the recited number minus 10% and any quantity that is higher such that “at least about 10” would include 9 and anything greater than 9. This term can also be expressed as “about 10 or more.” Similarly, the term “less than about” typically includes the recited number plus 10% and any quantity that is lower such that “less than about 10” would include 11 and anything less than 11. This term can also be expressed as “about 10 or less.”

Recitation of ranges of values herein are merely intended to serve as a shorthand method of referring individually to each separate value falling within the range, unless otherwise indicated herein, and each separate value is incorporated into the specification as if it were individually recited herein. All methods described herein can be performed in any suitable order unless otherwise indicated herein or otherwise clearly contradicted by context. The use of any and all examples, or exemplary language (e.g., “such as”) provided herein, is intended merely to illuminate certain materials and methods and does not pose a limitation on scope. No language in the specification should be construed as indicating any non-claimed element as essential to the practice of the disclosed materials and methods.

Although the operations of the methods herein are shown and described in a particular order, the order of the operations of each method may be altered so that certain operations may be performed in an inverse order or so that certain operation may be performed, at least in part, concurrently with other operations. In another embodiment, instructions or sub-operations of distinct operations may be in an intermittent and/or alternating manner.

It is to be understood that the above description is intended to be illustrative, and not restrictive. Many other embodiments will be apparent to those of skill in the art upon reading and understanding the above description. The scope of the disclosure should, therefore, be determined with reference to the appended claims, along with the full scope of equivalents to which such claims are entitled.

What is claimed is:

1. A device comprising:
a photonic integrated circuit (PIC) of a PIC structure, the PIC comprising a substrate and a waveguide structure disposed on a first side of the substrate, wherein the waveguide structure comprises an optical reflector disposed on a waveguide; and
a set of optical elements of the PIC structure, the set of optical elements being formed on a second side of the substrate opposite the first side of the substrate, wherein the optical reflector is configured reflect an optical signal received from the waveguide toward the set of optical elements.

2. The device of claim 1, wherein the set of optical elements comprises one or more microlenses.

3. The device of claim 1, wherein the set of optical elements comprises one or more metalenses.

4. The device of claim 1, wherein the set of optical elements is configured to collimate the optical signal.

5. The device of claim 1, wherein the optical reflector is an angled optical reflector disposed within the waveguide structure.

6. The device of claim 1, wherein the waveguide structure further comprises a grating coupler formed within the waveguide.

7. The device of claim 1, wherein the first side of the substrate is to be disposed on an electronic integrated circuit (EIC), and wherein the second side of the substrate is to be operatively coupled to an optical fiber connector.

8. A system comprising:
a printed circuit board;
an interposer disposed on the printed circuit board;
an electronic integrated circuit (EIC) disposed on the interposer; and
a photonic integrated circuit (PIC) structure comprising:
a PIC comprising a substrate, and a waveguide structure disposed on a first side of the substrate and the EIC, wherein the waveguide structure comprises an optical reflector disposed on a waveguide; and
a set of optical elements formed on a second side of the substrate opposite the first side of the substrate, wherein the optical reflector is configured reflect an optical signal received from the waveguide toward the set of optical elements.

9. The system of claim 8, wherein the set of optical elements comprises one or more microlenses.

10. The system of claim 8, wherein the set of optical elements comprises one or more metalenses.

11. The system of claim 8, wherein the set of optical elements is configured to collimate the optical signal.

12. The system of claim 8, wherein the optical reflector is an angled optical reflector disposed within the waveguide structure.

13. The system of claim 8, wherein the waveguide structure further comprises a grating coupler formed within the waveguide.

14. The system of claim 8, wherein the first side of the substrate is disposed on the EIC, and wherein the second side of the substrate is to be operatively coupled to an optical fiber connector.

15. A method comprising:
obtaining a substrate;
forming, on a first side of the substrate, a waveguide structure of a photonic integrated circuit (PIC) of a PIC structure, wherein the waveguide structure comprises an optical reflector disposed on a waveguide; and
forming, on a second side of the substrate opposite the first side of the substrate, a set of optical elements of the PIC structure, wherein the optical reflector is configured reflect an optical signal received from the waveguide toward the set of optical elements.

16. The method of claim 15, wherein the set of optical elements comprises one or more microlenses.

17. The method of claim 15, wherein the set of optical elements comprises one or more metalenses.

18. The method of claim 15, wherein the optical reflector is an angled optical reflector, and wherein forming the waveguide structure further comprises:
forming a trench within the waveguide;
forming the optical reflector within the trench; and
completing fabrication of the waveguide structure.

19. The method of claim 15, wherein the waveguide structure further comprises a grating coupler, and wherein forming the waveguide structure further comprising:
an optical reflector on the waveguide; and
completing fabrication of the waveguide structure.

20. The method of claim 15, wherein the first side of the substrate is to be disposed on an electronic integrated circuit (EIC), and wherein the second side of the substrate is to be operatively coupled to an optical fiber connector.
